(19) United States
(12) Patent Application Publication
(10) Pub. No.: US 2020/0023660 A1
(43) Pub. Date: Jan. 23, 2020

(54) AIR SUPPLY IN IMAGING DEVICES

(71) Applicant: Hewlett-Packard Development Company, L.P., Spring, TX (US)

(72) Inventors: Cheng-Qun Yang, Shanghai (CN); Yu-Mao Zhu, Shanghai (CN); Yue Yin Cai, Shanghai (CN); Xiao-Li Yang, Shanghai (CN)

(21) Appl. No.: 16/334,858

(22) PCT Filed: Sep. 29, 2016
(86) PCT No.: PCT/US2016/054531

§ 371 Date: Mar. 20, 2019

(51) Int. Cl. B41J 29/377; H05K 7/20

(52) U.S. Cl. CPC B41J 29/377; H05K 7/20172

(57) ABSTRACT

The present subject matter describes a system for air supply in an imaging device. In an example implementation, the system includes a mounting assembly to house a fan of the imaging device. The mounting assembly has at least two outlets to discharge air blown by the fan. The system further includes a first air guide and a second air guide. The first air guide is coupled to one of the at least two outlets to supply air from the fan to internal electrical components of the imaging device to dissipate heat generated by the internal electrical components. The second air guide is coupled to the other of the at least two outlets to supply air from the fan to a media output region of the imaging device to dissipate moisture in air escaping from the imaging device at the media output region.

### BACKGROUND

In home and office environments, document production and distribution are often performed by using different devices, such as printers, scanners, and photocopiers. These multiple functions of printing, scanning, photocopying, or the like may be performed by a single imaging device, such as a multi-function printer (MFP).

### BRIEF DESCRIPTION OF DRAWINGS

The following detailed description references the drawings, wherein:

FIG. 1 illustrates a system for handling air-flow in an imaging device, according to an example implementation of the present subject matter; and

FIG. 2 illustrates a side view of an imaging device, according to an example implementation of the present subject matter.

### DETAILED DESCRIPTION

Imaging devices, such as multi-function printers (MFPs) can perform different operations like fax, photocopy, scan, email, etc., in addition to printing operations. As these imaging devices perform multiple operations and are commonly used in office environments, these imaging devices strive to be compact and efficient for continuous use.

In an imaging device, generally, imaging substrates, such as papers, are stored in an input tray and fed from the input tray. Each of the imaging substrates moves inside the imaging device where an imaging operation, such as printing, is carried out on the respective imaging substrates. After completion of the imaging operation, the imaging substrate is dispensed through a substrate dispensing slot at a media output region of the imaging device.

In the imaging device, imaging substrates stored in an input tray often absorb moisture from the atmosphere. Thus, when the imaging substrate is fed from the input tray into the imaging device, a fusing unit in the imaging device generates heat for reducing the moisture content present within the imaging substrate. As the imaging substrate is heated, moisture from the imaging substrate evaporates to form water vapors which may escape through different vents and openings in the imaging device. Such water vapor may also escape through the substrate dispensing slot at the media output region. The water vapors escaping at the media output region come in contact with cooler atmospheric air at the media output region and cold outer surfaces of the imaging device. On coming in contact with the cooler atmospheric air and the outer surfaces of the imaging device, the vapors may abruptly cool down and condense to form water droplets on the outer surfaces of the imaging device. Thus, water droplets are accumulated on the outer surfaces, such as a cover of the imaging device that partly encloses the media output region. After completion of the imaging operation, as the imaging substrate is dispensed at the media output region, the water droplets accumulated on the cover at the media output region may fall on the imaging substrate and may cause smudging or smearing of ink on the imaging substrate. This degrades the quality of the printouts that are obtained from the imaging device.

Further, due to compact nature of these imaging devices, the media output region is small and thus the moisture laden air escaping from the imaging device does not get effectively dispersed in the atmosphere which increases the concentration of moist air at the media output region. This further increases the chances of abrupt condensation and formation of water droplets. In addition, the chances of condensation and formation of water droplets becomes acute when the print volume is high and the surrounding outside atmosphere is cooler.

The present subject matter relates to systems for handling air-flow in an imaging device and imaging devices having such systems. Such systems increase air flow at the media output region, which in turn may disperse the moist air. This may eliminate or reduce condensation of water droplets at the media output region to facilitate printouts of improved quality.

In an example implementation, the system of the present subject matter includes a mounting assembly for housing a fan. The mounting assembly has at least two outlets to discharge air blown by the fan. The two outlets of the mounting assembly are configured to flow air in two different regions, such as to a media output region and to internal electrical components of the imaging device. A first air guide is coupled to one of the at least two outlets, and a second air guide coupled to the other of the at least two outlets.

In an example implementation, the first and second air guides may be air ducts or pipes used to transmit air from one point to another. The first air guide may supply air from the fan to internal electrical components of the imaging device to dissipate heat generated by the internal electrical components. The second air guide may supply air from the fan to a media output region of the imaging device to dissipate moisture in air escaping from the imaging device at the media output region. As the moist air escaping at the media output region is dispersed by the air blown from the fan, the moist air does not condense on the cold surfaces at the media output region. This prevents formation of water droplets on the cold surfaces at the media output region and eventually prevents smudging of ink on the imaging substrate.

Further, the systems of the present subject matter enable use of a single fan for cooling the internal electrical components of the imaging device and for driving out the moist air from the media output region. Using the same fan for cooling the electrical components and for driving out moist air, helps in making the imaging device compact.

The following detailed description refers to the accompanying drawings. Wherever possible, the same reference numbers are used in the drawings and the following description to refer to the same or similar parts. While several examples are described in the description, modifications, adaptations, and other implementations are possible. Accordingly, the following detailed description does not limit the disclosed examples. Instead, the proper scope of the disclosed examples may be defined by the appended claims.

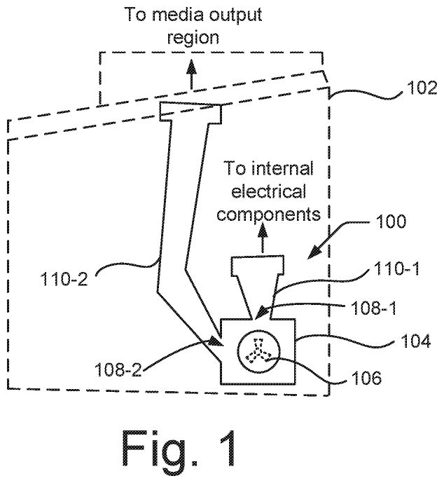

FIG. 1 illustrates a system 100 for handling air-flow in an imaging device 102, according to an example implementation of the present subject matter. The system 100, also referred to as an air-flow system, may be installed in the imaging device 102. The system 100 includes a mounting assembly 104 configured to house a fan 106. The fan 106 may be a fan of the imaging device 102. In an example implementation, the mounting assembly 104 may be a fan mount for the imaging device 102. As shown in FIG. 1, the mounting assembly 104 has two outlets, viz., a first outlet 108-1 and a second outlet 108-2. The outlets are openings in the mounting assembly 104 which enable discharge of air blown by the fan 106 through the outlets. The system 100 includes a first air guide 110-1 coupled to the first outlet 108-1 and a second air guide 110-2 coupled to the second outlet 108-2. In an example implementation, the first air guide 110-1 and the second air guide 110-2 may be integrated with the mounting assembly 104. Although, the mounting assembly 104 is shown to have two outlets, in an example implementation, the mounting assembly may have more than two outlets, where other outlets may be used for supplying air to other regions/components of the imaging device 102.

The first air guide 110-1 coupled to the first outlet 108-1 is configured to supply air from the fan 106 to internal electrical components (not shown) of the imaging device 102 and the second air guide 110-2 coupled to the second outlet 108-2 is configured to supply air from the fan 106 to a media output region of the imaging device 102. Air is supplied to the internal electrical components to dissipate the heat generated by the internal electrical components, and air is supplied to the media output region to dissipate moisture in air escaping from the imaging device 102 at the media output region.

Thus, the system 100 by flowing air at the media output region may eliminate or reduce condensation of water vapors escaping from the imaging device 102 at the media output region and hence prevent accumulation of water droplets at the media output region. This may eliminate smudging of ink in printed imaging substrates received at the media output region. Further, the system 100 by using the same fan 106 to supply air to both the internal electrical components and to the media output region enables the imaging device to maintain its compactness.

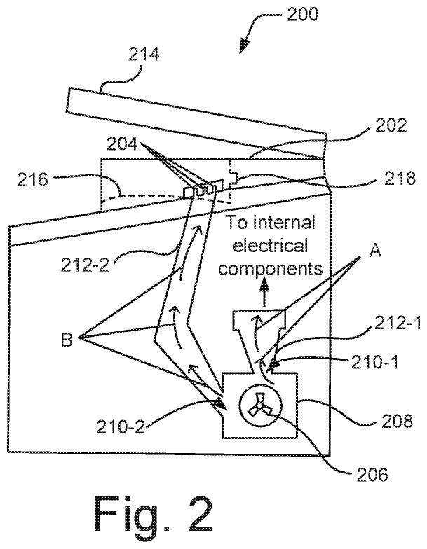

FIG. 2 illustrates a side view of an imaging device 200, according to an example implementation of the present subject matter. In an example implementation, the imaging device 200 is a multi-function printer (MFP) that can perform a variety of operations, such as print, scan, photocopy, fax, email, etc. The imaging device 200 has an input tray (not shown) which feeds an imaging substrate into the imaging device 200. After, the imaging substrate is fed, imaging operations, such as printing or photocopying can be performed on the imaging substrate which is then received at a media output region of the imaging device 200.

In an example implementation, the imaging device 200 includes a cover 202 that at least partly encloses the media output region. The cover 202 has a base surface 216 to receive the imaging substrate dispensed by the imaging device 200 at the media output region after the imaging operations are performed. The cover 202 also includes a casing surrounding the base surface 216. The casing has a slot 218 along an edge of the casing for dispensing the imaging substrate on the base surface 216. The slot 218 may also be referred to as a substrate dispensing slot 218. As shown in FIG. 2, an automatic document feeder (ADF) panel 214 at least partly overhangs the cover 202. In an example implementation, the ADF panel 214 may be used to feed documents for photocopying or scanning.

The cover 202 has a plurality of air-flow vents 204. Although, FIG. 2 shows three air-flow vents, the cover 202 may have two air-flow vents or more than three air-flow vents. The air-flow vents 204 are formed in the casing of the cover 202 in such a manner that air flowing through the air-flow vents 204 is directed along the edge of the casing having the substrate dispensing slot 218. Thus, the positioning of the air-flow vents 204 on the casing facilitate the air to be flowed through the air-flow vents 204 along the substrate dispensing slot 218 to the media output region.

As shown in FIG. 2, the imaging device 200 has a fan 206. In an example implementation, the fan 206 is a cooling fan for reducing the heat generated by internal electrical components of the imaging device 200. The internal electrical components may include, for example, electrical motors, printed circuit boards (PCBs), and other internal hardware components of the imaging device 200.

The imaging device 200 includes a fan mount for housing the fan 206 of the imaging device 200. In an example implementation, the fan mount is a mounting assembly 208 shown in FIG. 2. The mounting assembly 208, as shown in FIG. 2, has a first outlet 210-1 and a second outlet 210-2. The first and second outlets 210-1 and 210-2 can discharge air blown by the fan 206. In an example implementation, the mounting assembly 208 is formed by injection molding of plastic. Although in FIG. 2, the mounting assembly 208 is shown to have two outlets, in an example implementation, the mounting assembly may have more than two outlets to supply air to other regions/components of the imaging device 200.

The imaging device 200 also includes a first air guide 212-1. In an example implementation, the first air-guide 212-1 may be an air duct made of injection molded plastic. The first air guide 212-1 is coupled to the first outlet 210-1. The first air guide 212-1 may be coupled to the first outlet 210-1 by a snug fit. In an example implementation, the first air guide 212-1 may be integrated with the mounting assembly 208. One end of the first air guide 212-1 is connected to the first outlet 210-1 and other end of the first air-guide 212-1 leads to the internal electrical components of the imaging device 200. Thus, the first air-guide 212-1 can supply air from the fan 206 to the internal electrical components to dissipate heat generated by the internal electrical components.

The imaging device 200 further includes a second air guide 212-2. In an example implementation, the second air-guide 212-2 may be another air duct made of injection molded plastic. The second air guide 212-2 is coupled to the second outlet 210-2. The second air guide 212-2 may be coupled to the second outlet 210-2 by a snug fit. In an example implementation, the second air guide 212-1 may be integrated with the mounting assembly 208. One end of the second air guide 212-2 is connected to the second outlet 210-2 and other end of the second air-guide 212-2 is connected to the plurality of air-flow vents 204 on the cover 202. Thus, the second air-guide 212-2 provides an air-flow path connecting the second outlet 210-2 with the plurality of air-flow vents 204 and supplies air from the fan 206 through the air-flow vents 204 to the media output region. This air flowed through the second-air guide 212-2 to the media output region dissipates moisture in air escaping from the imaging device 200 at the media output region and prevents formation of undesired water droplets at the media output region.

The description hereinafter elaborates the operation of the imaging device 200 when the imaging device 200 is connected to a power source and engaged for performing imaging operations. During operation of the imaging device 200, an imaging substrate may be fed in the imaging device 200 from an input tray (not shown) of the imaging device 200. As the imaging substrate moves inside the imaging device 200, the imaging operations, such as printing may be performed on the imaging substrate. After completion of the imaging operation, the imaging device 200 dispenses the imaging substrate on the base surface 216 of the cover 202 through the substrate dispensing slot 218.

As power is supplied to the imaging device 200, the fan 206 also operates to blow air. The air blown by the fan 206 is discharged through the first and second outlets 210-1 and 210-2. Air discharged through the first outlet 210-1 travels through the first air guide 212-1, as indicated by the set of arrows A, and is flowed on the internal electrical components of the imaging device 200. Air discharged through the second outlet 210-2 travels through the second air guide 212-2, as indicated by the set of arrows B, and is flowed through the plurality of air-flow vents 204. The air flowing through the air-flow vents 204 is directed along the substrate dispensing slot 218 in the cover 202 to the media output region. This air flowed from the fan 206 to the media output region prevents condensation of moist air released from the imaging device 200 at the media output region and may eliminate accumulation of water droplets at the media output region. Thus, chances of smearing of the ink, by falling of water droplets on freshly printed imaging substrate at the media output region may reduce.

Although implementations for an air-flow system in an imaging device are described in language specific to methods and/or structural features, it is to be understood that the present subject matter is not limited to the specific methods or features described. Rather, the methods and specific features are disclosed and explained as example implementations for air-flow systems.

We claim:

1. A system comprising:
a mounting assembly to house a fan of an imaging device, the mounting assembly having at least two outlets to discharge air blown by the fan;
a first air guide coupled to one of the at least two outlets to supply air from the fan to internal electrical components of the imaging device to dissipate heat generated by the internal electrical components; and
a second air guide coupled to the other of the at least two outlets to supply air from the fan to a media output region of the imaging device to dissipate moisture in air escaping from the imaging device at the media output region.

2. The system as claimed in claim 1, wherein the second air guide is to connect the other of the at least two outlets with a plurality of air-flow vents on a cover enclosing the media output region to supply the air to the media output region through the plurality of air-flow vents.

3. The system as claimed in claim 1, wherein the first air guide is integrated with the mounting assembly.

4. The system as claimed in claim 1, wherein the second air guide is integrated with the mounting assembly.

5. The system as claimed in claim 1, wherein the mounting assembly, the first air guide, and the second air guide are made of injection molded plastic.

6. An air-flow system comprising:
a fan mount for an imaging device, the fan mount having a first outlet and a second outlet to discharge air blown by a fan of the imaging device;
a first air guide coupled to the first outlet to supply air from the fan to internal electrical components of the imaging device to dissipate heat generated by the internal electrical components; and
a second air guide coupled to the second outlet to supply air from the fan to a media output region of the imaging device to dissipate moisture in air escaping from the imaging device at the media output region.

7. The air-flow system as claimed in claim 6, wherein the second air guide is to connect the second outlet with a plurality of air-flow vents on a cover enclosing the media output region such that air through the plurality of air-flow vents is flowed along a substrate dispensing slot in the cover to the media output region.

8. The air-flow system as claimed in claim 6, wherein the first air guide is coupled to the first outlet by a snug fit.

9. The air-flow system as claimed in claim 6, wherein the second air guide is coupled to the second outlet by a snug fit.

10. The system as claimed in claim 6, wherein the fan mount, the first air guide, and the second air guide are made of injection molded plastic.

11. An imaging device comprising:
a fan;
a mounting assembly housing the fan, the mounting assembly having a first outlet and a second outlet to discharge air blown by the fan;
a first air guide coupled to the first outlet to supply air from the fan to internal electrical components of the imaging device to dissipate heat generated by the internal electrical components; and
a second air guide coupled to the second outlet to supply air from the fan to a media output region of the imaging device to dissipate moisture in air escaping from the imaging device at the media output region.

12. The imaging device as claimed in claim 11, further comprising a cover at least partly enclosing the media output region, the cover having a plurality of air-flow vents.

13. The imaging device as claimed in claim 12, wherein the second air guide is to connect the second outlet with the plurality of air-flow vents to supply the air to the media output region through the plurality of air-flow vents.

14. The imaging device as claimed in claim 12, further comprising an automatic document feeder panel at least partly overhanging the cover.

15. The imaging device as claimed in claim 12, wherein the cover comprises:
a base surface to receive an imaging substrate dispensed at the media output region; and
a casing surrounding the base surface and having a slot along an edge of the casing for dispensing the imaging substrate on the base surface, wherein the plurality of air-flow vents are formed in the casing such that air flowing through the plurality of air-flow vents is directed along the edge of the casing.
